(19) United States
(12) Patent Application Publication
(10) Pub. No.: US 2008/0046789 A1
(43) Pub. Date: Feb. 21, 2008

(54) APPARATUS AND METHOD FOR TESTING MEMORY DEVICES AND CIRCUITS IN INTEGRATED CIRCUITS

(76) Inventors: Igor Arsovski, Williston, VT (US); Valerie Chickanosky, South Burlington, VT (US); Rahul Nadkarni, Greenville, NC (US); Michael Oucllette, Westford, VT (US); Reid Wistort, Westford, VT (US)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/465,864

(22) Filed: Aug. 21, 2006

(51) Int. Cl. G01R 31/28

(52) U.S. Cl. 714/733

(57) ABSTRACT

This patent describes a method for varying the amplitude and frequency of power supply oscillations produced by content addressable memories or other critical circuits using BIST. Supply oscillations are produced by performing noisy (high switching activity—high current demand) searches followed by quiet (low switching activity—low current demand) searches. The amplitude and frequency of oscillations can be varied by changing the number of noisy and quiet searches e.g. pattern 1-noisy quiet, noisy, quiet; pattern 2-noisy, noisy, quiet, noisy, noisy, quiet, etc. By going through different patterns the current demand from the CAM macro increases the likelihood of producing worst—case noise and enables testing of CAM operation as well as surrounding circuitry in these noisy conditions.

### BACKGROUND OF THE INVENTION

1. Field of the Invention

This invention relates to testing and operation of integrated circuits, and particularly to testing memory operation and surrounding circuits.

2. Background

Most integrated circuits; hereinafter also referred to as IC devices, IC chips, Application Specific Integrated Circuits (ASICs) or IC boards, contain a multitude of components such as transistors, capacitors, resistors, processors logic gates (for example AND, OR, NAND, and NOR, etc), I/O drivers, voltage islands, and memory devices (for example DRAM, SRAM, CAM, RA etc.) These components are placed on a substrate material and are connected by a series of electrical traces (i.e., conductors). Most components receive power via a power distribution bus, which is connected between one or more power supplies.

Data signals are passed between components via the traces. The route used to pass a data signal between components is referred to as a data path. The coupling of a data signal from one trace (usually called the aggressor) to another trace (usually called a victim) is referred to as cross talk, whereas the variation of power supply voltage from its normal value due to variable current demand is referred to as power supply noise.

Today's integrated circuits benefit from two major improvements over integrated circuits constructed a few years ago. The first improvement encompasses the integrated circuits that operate at lower voltages than their predecessors. Thus, systems employing today's integrated circuits consume less power than systems employing older integrated circuits, and as such are extremely beneficial for portable devices for example.

The second improvement encompasses component density. Current integrated circuits have higher component densities than their predecessors. In other words, current integrated circuits have more components packed within a given area than older integrated circuits. Higher density integrated circuits allow manufacturers either to offer smaller devices, which perform the same functions as older devices, or to offer similar sized devices with additional functions.

Undesirable effects, however, have accompanied the shift to higher density, lower voltage integrated circuits. For example, power supply noise and cross-talk have an increased effect on internal circuit path delays. Power supply noise and cross talk that would have barely been noticeable within older integrated circuits may render current integrated circuits inoperable.

Compounding the problems caused by power supply noise and cross-talk is the lack of adequate testing methods to measure their effects on signal delays (among others) within the integrated circuit. For example, power supply noise and cross-talk effects are usually frequency dependent. Thus, during manufacture, a chip may pass a low frequency functional test, but fail to properly function when placed and operated within a system at normal operating frequency.

Power supply noise is generated by semiconductor devices that draw a large amount of current and/or vary this current demand across a single cycle or across multiple cycles. The large current draw causes a resistive voltage drop of the power supply voltage while the variable current draw, causes both an inductive voltage drop (Ldi/dt), as well as power-supply voltage oscillations. Among the major contributors to power supply noise are memory devices such as Content Addressable Memories (CAMs), Static Random Access Memories (SRAMs), and Register Arrays (RAs), which can draw a significant amount of current due to high switching activity. CAMs are especially notorious because of their ability to execute a fully,parallel compare operation that activates the entire memory in a single clock cycle. Several circuit techniques (e.g. two stage compare) have been used to reduce the switching activity in a typical CAM search operation. However, most of those techniques rely on statistical assumptions to reduce the average power consumption and do not address the worst-case switching activity that can generate power supply noise. This power supply noise can vary in amplitude with the operation of certain IC devices causing power supply oscillation. These oscillations in the supply voltage can cause failure of the aggressor circuits themselves or they can cause failure of adjacent victim circuits. Sensitive analog circuits like Phase-Locked Loops (PLL), and Analog to Digital Converters (ADC) are particularly vulnerable to power supply oscillations.

As the technology scales, the supply voltage has to be lowered accordingly for gate-oxide reliability. As supply voltage is reduced, power supply noise becomes more dominant. Furthermore, the frequency of power supply oscillations depends upon the current demand from the aggressor circuit as well as the circuit environment. For any given application specific IC, the impact of the oscillation frequency will produce different effects; these effects may potentially cause failures in different parts of the chip.

A need exists, therefore, for an apparatus and method for dynamically determining the effects of certain devices which cause noise which may affect memory circuits and other sensitive circuits while the integrated circuit is operating in its normal mode. Furthermore, a need exists for an apparatus and method that allows the determination to be made quickly.

### SUMMARY OF THE INVENTION

The shortcomings of the prior art are overcome and additional advantages are provided by testing IC for the power supply noise that may be generated by certain critical circuits that have a data-dependent current draw or can draw significant current during switching or transitioning between quiet events (low current demand) to noisy events (high current demand). When such circuits transition from quiet events to noisy events, they produce a sudden increase in current demand from the power supply. The sudden current requirement from such circuits causes resistive as well as inductive droop in the supply voltage. When those circuits transition back from noisy events to quiet events, the current requirement greatly diminishes and that causes the power supply voltage to bounce up. The high-current-demand (noisy) cycles followed by low-current-demand (quiet) cycles produce power-supply voltage oscillations. It has been found that such critical circuits include memory devices such as Content Addressable Memories (CAMs), Static Random Access Memories (SRAMs), Register Arrays (RAs) that can draw significant amount of current due to high switching activity. In addition, other critical circuits include I/O drivers, voltage islands, and other circuits, which create significant variation in their current demand over their normal operation.

CAMs are especially notorious for causing power supply noise because they demand a large amount of current when executing a fully parallel search operation, which activates the entire memory array in a single clock cycle. Accordingly, CAM will be used as an example of a critical circuit that will be used to produce and test worst-case noise in an integrated circuit.

Other critical circuits could have been used to generate and the test the effects of power supply noise. Devices such as, SRAMs, or I/O drivers, or Voltage Islands that draw significant amount of current during transitions of their operation. For example, Static Random Access Memories (SRAMs) can also draw variable current during read and write operations. During a read operation bit lines discharge partially and have to be pre-charged at the end of the cycle, sense amplifiers switch, output latches can switch if the data changes and can draw significant current when they drive large output loads. During a write operation the bit lines discharge completely at the beginning of the cycle and have to be pre-charged at the end of the cycle drawing large current. Additionally during a read or write operation, switching of the address and data inputs can draw more current. Such high switching activity (noisy) read and write cycles draw large current from the supply. SRAMs can also have low switching activity (quiet) read and write cycles. SRAMs typically have bit-enable inputs associated with the data inputs that can be used to enable or disable read or write to the corresponding bit. If most of the bit-enable inputs are disabled, the switching activity in the SRAM during a read or write operation is significantly reduced because the corresponding bit-lines don't discharge, the corresponding sense-amplifiers and data-output latches do not switch as well. For multi-port SRAMs, noisy cycles are ones where all ports are accessed and each port performs a noisy read or write operation. And quiet cycles are ones where only one port is accessed, the rest of the ports are inactive and the accessed port does a quiet read or write operation described earlier.

Another example of a critical circuit is output drivers that drive large off-chip capacitance and have data dependent current demand. output driver driving a constant output value demands less current than an output driver that constantly switches from driving a logic “1” to driving a logic “0” and than back to driving a logic “1” output. Thus, similar to semiconductor memories, depending on the input data, I/O drivers can produce both noisy and quiet events on ICs.

Voltage Islands are another good example of critical circuits where blocks of the integrated circuit have a variable current demand. Typically used to reduce leakage power of inactive areas of the IC, the voltage island power-up/power-down feature can demand both large and variable current from the IC power supply. As in the case of other critical circuits, this large variable current draw can cause large power-supply noise in both the resistive and inductive voltage drop form.

When such critical circuits transition from quiet events (low current demand) to noisy events (high current demand), they produce a sudden increase in current demand from the supply. The sudden current requirement from such circuits causes resistive as well as inductive droop in the supply voltage. When those circuits transition back from noisy events to quiet events, the current requirement greatly diminishes and that causes the supply voltage to bounce up. The high-current-demand (noisy) cycles followed by low-current-demand (quiet) cycles produce power-supply oscillations. When such critical circuits transition from low-current-demand (quiet) cycles to high-current-demand (noisy) cycles and then transition back to low-current-demand cycles, they produce oscillations in the supply voltage. These oscillations in the power supply voltage cause noise with varying frequency and amplitude and can be therefore used as a worst-case testing mechanism for sensitive circuits on the IC. For example, the oscillation frequency of the power supply depends on the current demand of the aggressor circuit as well as the RLC environment of the power supply net. An integrated circuit having a critical circuit generates a characteristic oscillation frequency for a single noisy cycle followed by a number of quiet cycles which will be different than that for two noisy cycles followed by quiet cycles. The oscillation frequency for four noisy cycles followed by quiet cycles will be different from the first two cases. The different frequency of noisy-quiet events has a direct effect on the power-supply oscillations. Also, different supply oscillation frequencies may potentially cause failures in different parts of the chip. So it is not only important to produce worst-case noise events during chip testing, it is also important to change the frequency of supply oscillations by having the ability to program the number of noisy and quiet cycles. This invention utilizes a built-in self-test (BIST) method to address both those aspects. Although the discussion will focus on the testing of Content Addressable Memories (CAMs), it can be adapted to test the other critical circuits, including memory devices as well.

Since all entries are activated during a search operation, CAMs can consume a lot of power and draw a large current from the power supply. Match-line (ML) and search-line (SL) switching are the biggest contributors to the CAM power and noise. Typically in CAMs, to save power, search is done in two stages. In the pre-compare stage, only a small subset of bits is compared. If that comparison for an entry results in a mismatch, the rest of the entry is ignored in the main-compare stage. Only those entries that matched in the pre-compare stage are compared in the second stage. From a statistical standpoint, most of the entries will mismatch in the pre-compare stage and only consume a fraction of the total possible matchline power. However, it is possible to have a single cycle or a handful of cycles where all entries match in the pre-compare stage.

It is imperative to understand which circuits contribute to causing the power supply voltage to fluctuate and cause the noise so that the noise may later be used to properly test the integrated circuit. For noise analysis, it is important to analyze the worst-case (highest current demand) scenario. In an integrated circuit that contains a CAM this occurs during the highest switching activity in search mode when all data inputs switch causing all search lines to switch, or when all entries match in the pre-compare stage, or when all outputs switch.

Current profile of a CAM with one noisy search occurs in three major peaks corresponding to switching of searchlines, switching of matchlines and switching due to combination of field outputs. Multiple noisy searches for the same CAM configuration generate the current profile like the single noisy search replicated multiple times.

As the number of noisy searches goes up, the amplitude of supply oscillations goes up. The oscillation frequency changes as the number of noisy cycles changes. If the peaks and troughs created by the noise demand match up with the critical frequency of the chip RLC environment, it will cause the most damage in terms of noise-induced fails. Therefore, there is a clear need for having the ability to change the amplitude and frequency of the current demand in order to expose the worst case power supply voltage oscillations and test under the worst-case noise.

The number of noisy cycles and quiet cycles can be programmed into an off-chip or on chip tester by loading the counter latches in the tester controller. Preferably, this could be accomplished using a BIST controller during the initialization of the IC. Since the amplitude and frequency of supply oscillations and its effects will vary from one ASIC chip design to another, initial testing needs to be done for each ASIC chip design to determine the setting(s) that would give worst case results. This creates a characteristic quiescent “Q” point for each ASIC design. This Q point could then be used to test each chip of that particular ASIC design by exciting the power delivery system to determine the impedance versus frequency of the noise generated by the power delivery system. The power delivery system could be off-chip or on-chip and as previously mentioned such testing may be extended to systems other than those using a CAM.

Additional features and advantages are realized through the techniques of the present invention. Other embodiments and aspects of the invention are described in detail herein and are considered a part of the claimed invention. For a better understanding of the invention with advantages and features, refer to the description and drawings.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates an example of General CAM Architecture

FIG. 2 illustrates CAM induced power supply compression

FIG. 3 illustrates a sample current demand from a single noisy CAM search:

FIG. 4 illustrates a sample current demand from four noisy CAM searches and

FIG. 5 illustrates power supply voltage compression caused by 1, 2 or 4 noisy searches each followed by quiet cycles.

The following detailed description explains the preferred embodiments of the invention, together with advantages and features, by way of example with reference to the drawings.

### DETAILED DESCRIPTION OF THE INVENTION

Turning now to the drawings in greater detail, we will discuss the architecture and operation of the CAM and technique to generate noise using built in system test (BIST) circuits to test memory and adjacent circuits.

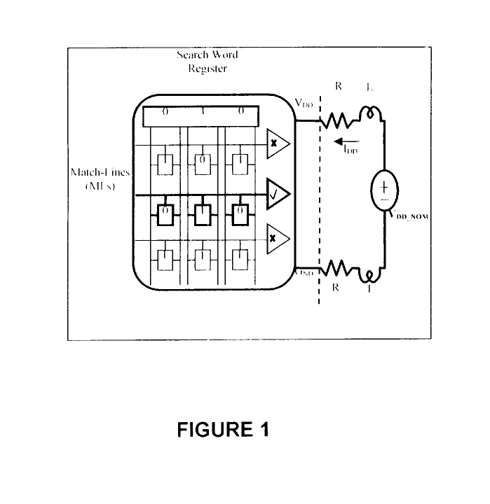

Content Addressable Memory (CAM) is an application specific memory designed to accelerate the search of large look-up tables. CAM is commonly used for applications such as address translation in network routers, TLBs in processor caches, pattern recognition, and data compression. CAM is an attractive solution for these applications because it performs a fully parallel search of the entire look-up table, and, regardless of table size, returns a search result within nanoseconds. FIG. 1 shows a simple CAM architecture that illustrates how this fast search operation is performed. During the search operation the search data in the Search Word Register is supplied to every CAM word via Search-Lines (SLs), compared to every stored word in every entry, and the results of this comparison are displayed on all Match-Lines (MLs). Since both SLs and MLs are highly capacitive and switch every search cycle, CAM causes high power consumption and severe on-chip supply noise.

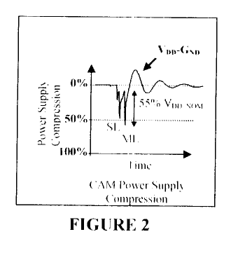

During a search operation, CAM can draw high current (I_{DD}), causing significant power supply voltage compression in the form of VDD droop and GND bounce. FIG. 2 shows a typical CAM voltage compression waveform for a CAM using virtual-GND pre-charge-high ML sensing scheme. This waveform illustrates the SL and ML components, which cause the high voltage compression. Without the heavy use of decoupling capacitance, which is both area and yield expensive, this CAM sensing can cause voltage compression exceeding ½ V_{DD}. This power-supply noise is especially of concern in Embedded CAM (eCAM), which shares its environment with noise-sensitive circuits. The large supply voltage compression can not only cause failure in the CAM but also affect the neighboring circuits that may be noise-sensitive. Technology scaling further aggravates this problem by decreasing voltage headroom while increasing both current density, which exacerbates the resistive voltage drop, and transition speed, which enlarges Ldi/dt noise.

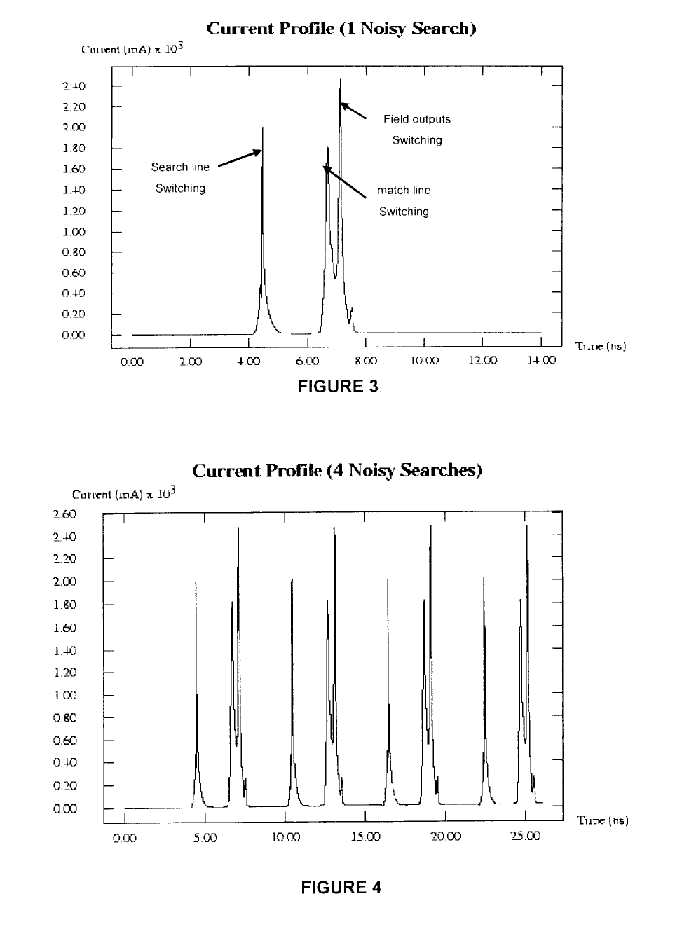

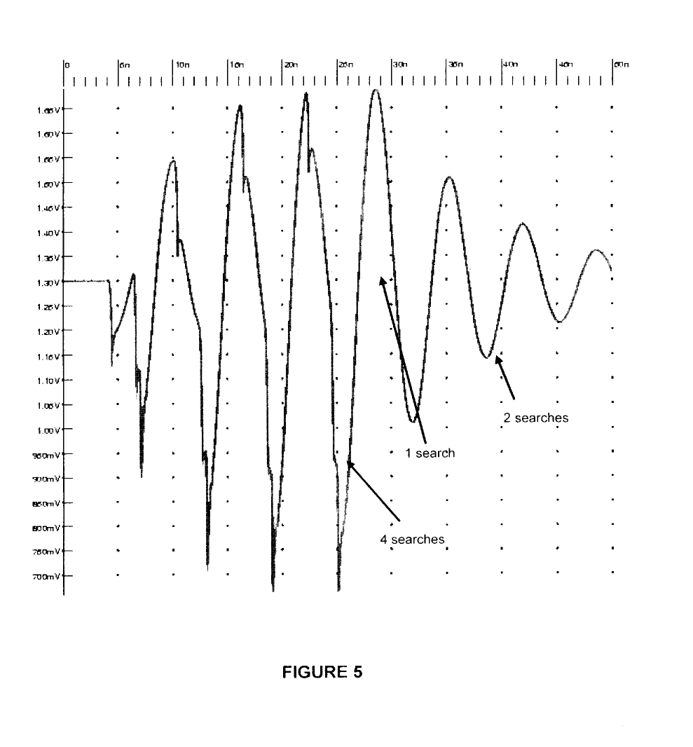

FIG. 3 illustrates a current profile for a CAM performing a single noisy search. Peaks in the current occur during search-line switching, match-line switching, and field output switching. FIG. 4 illustrates the current demand of a power supply during four noisy searches. FIG. 5 illustrates the effect of one, two, and four noisy searches on the power supply. The BIST is programmed in accordance with the present invention to provide the worst-case scenario described previously, the peaks and troughs created by the noise demand will match up with the critical frequency of the particular chip environment of each ASIC CAM design, so that it will cause the most damage in terms of the noise-induced fails. It is necessary therefore to be able to determine the frequency and amplitude of the power delivery system oscillations that produce the worst-case noise.

Since the amplitude and frequency will vary for each ASIC design using CAM, it is necessary to provide a means to obtain the Q point for the worst-case condition of each individual ASIC design to excite or disturb the power supply system thereby injecting the noise into the ASIC under test. The ASIC design must initially be exercised by the BIST under controlled conditions to determine the worst-case condition.

The BIST patterns are used to change the switching of the CAM to vary the amplitude and frequency of the power delivery system in order to produce the worst-case noise condition and the Q point of the ASIC design under study. These patterns should test the effects of the power-supply compression and preferably use noisy cycles followed by quiet cycles using a programmable BIST in order to produce high switching activity-high current demand and low switching activity-low current demand. Such patterns include generating:
1. noisy matches followed by quiet matches; or
2. noisy search followed by quiet mismatches; or
3. matches followed by all-bit mismatches; or
4. single bit mismatch (noisy followed by quiet cycles),
   Each of these patterns has the potential to produce the worst-case condition depending on the ASIC design under test. It should be understood that the details of these patterns are given by way of examples and that other patterns may also be used in keeping within the scope of the present invention.

For example, the first pattern performs a noisy-quiet-noisy-quiet match sequence. Where the number of consecutive noisy searches can be varied from 1 to 16 and the number of consecutive quiet searches can be independently varied from 1 to 16. This pattern generates a current demand that has a variable frequency and allows the BIST to zero in on the critical frequency of the power supply net. When the worst case power supply noise is induced the CAM as well as other adjacent circuits sensitive to noise can be tested for proper functionality.

The second pattern performs a noisy match-noisy mismatch-quiet mismatch-noisy match-noisy mismatch-quiet mismatch sequence. The number of consecutive noisy match, noisy mismatch pairs can be varied from 1 to 16. The number of consecutive quiet mismatch cycles can be independently varied from 1 to 16. This pattern activates a number of high current demand circuits in the CAM while also testing power supply noise sensitive operations. Like the previous pattern this pattern can also be used to generate noise to test other CAM adjacent circuits that may be sensitive to noise.

The third pattern performs a noisy match-noisy mismatch sequence. The number of consecutive matches can be varied from 1 to 16. The number of mismatches can be independently varied from 1 to 16. This pattern generates noise due to switching of lines, match-lines, field outputs, and macro outputs. The pattern tests the effects of noise on the ability of match-line to pull up to the match voltage as well as discharge to the mismatch voltage. It can also be used to generate noise to test other adjacent circuits that may be sensitive to noise.

The fourth pattern performs a noisy single bit mismatch-quiet single bit mismatch sequence. The number of noisy single-bit mismatch cycles can be varied from 1 to 16. The number of quiet single-bit mismatch cycles can be independently varied from 1 to 16. This pattern generates noise by activating another subset of high current demand circuits and then testing another set of sensitive operations. It can also be used to generate noise to test other adjacent circuits that may be sensitive to noise.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. Method for testing an integrated circuit having a critical noise generating circuit comprising:
providing an integrated circuit having a power delivery system and the critical circuit;
switching the critical circuit with a predetermined pattern to generate significant current fluctuations to produce a critical amount of power supply noise.

2. The method of claim 1 wherein the critical circuit is a memory device.

3. The method of claim 2 wherein the memory device is a CAM.

4. The method of claim 3 wherein the switching occurs during search operation.

5. The method of claim 1 wherein the switching is generated by a programmable BIST using a test pattern.

6. The method of claim 5 wherein the test pattern produces a worst-case noise condition for the integrated circuit.

7. The method claim 6 wherein the test pattern performs a series of noisy—quiet match sequences.

8. The method of claim 6 wherein the test pattern performs a series of noisy searches followed by quiet mismatches.

9. The method of claim 6 wherein the test pattern performs a noisy match followed by noisy mismatches.

10. The method of claim 6 wherein the test pattern performs a single bit noisy mismatch followed by single bit quiet mismatch cycles.

11. Apparatus for testing an integrated circuit having multiple circuits and a critical noise generating circuit comprising:
a power distribution system with an output that supplies power to the circuits and the critical noise generating circuit;
the critical noise generating circuit that causes significant current fluctuations when switched;
a device that switches the critical noise generating circuit with a predetermined pattern to produce a critical amount of power supply noise.

12. The apparatus of claim 11 wherein the device used for switching is a programmable BIST, which generates test patterns to the memory device to produce a worst-case noise condition for the integrated circuit.

13. The apparatus of claim 11 wherein the critical noise generating circuit is a memory device.

14. The apparatus of claim 13 wherein the memory device is a CAM.

15. The apparatus of claiml4 wherein the CAM is switched during search operation.

16. The apparatus of claim 15 the CAM has match lines and search lines, which cause current fluctuations when switched;

17. The apparatus of claim 13 wherein the test pattern performs a series of noisy—quiet match sequences.

18. The apparatus of claim 13 wherein the test pattern performs a series of noisy searches followed by quiet mismatches.

19. The apparatus of claim 13 wherein the test pattern performs a noisy match followed by noisy mismatches.

20. The apparatus of claim 13 wherein the test pattern performs a single bit noisy mismatch followed by single bit quiet mismatch cycles.
